(19) United States
(12) Patent Application Publication
(10) Pub. No.: US 2011/0042699 A1
(43) Pub. Date: Feb. 24, 2011

(54) Substrate for light emitting diode package and light emitting diode package having the same

(75) Inventors: Sung Keun Park, Suwon (KR); Seog Moon Choi, Seoul (KR); Young Ho Sohn, Suwon (KR); Tae Hyun Kim, Seoul (KR); Young Ki Lee, Hwaseong (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD,, Suwon (KR)

(21) Appl. No.: 12/654,431

(22) Filed: Dec. 18, 2009

(30) Foreign Application Priority Data
Aug. 24, 2009 (KR) 10-2009-0078403

(51) Int. Cl. H01L 33/00

(52) U.S. Cl. 257/98; 257/99; 438/26; 257/E33.059; 257/E33.066

(57) ABSTRACT

A substrate for a light emitting diode (LED) package, and an LED package having the same are disclosed. The substrate for an LED package includes: a metal plate; an insulation oxide layer formed on a portion of the surface of the metal plate; a first conductive pattern formed at one region of the insulation oxide layer and providing a light emitting diode mounting area; and a second conductive pattern formed at another region of the insulation oxide layer such that it is separated from the first conductive pattern. In the substrate for an LED package, because regions of the insulation oxide layer other than regions for insulating conductive patterns are removed, heat generated from the light emitting diode can be effectively released. In addition, degradation of reflexibility and luminance of the LED due to the insulation oxide layer can be prevented.

### CROSS-REFERENCE TO RELATED APPLICATIONS

This application claims the priority of Korean Patent Application No. 10-2009-0078403 filed on Aug. 24, 2009, in the Korean Intellectual Property Office, the disclosure of which is incorporated herein by reference.

### BACKGROUND OF THE INVENTION

1. Field of the Invention

The present invention relates to a metal substrate for a light emitting diode package and a light emitting diode package having the same and, more particularly, to a metal substrate for a light emitting diode package having high heat release properties, high luminance, and high reflexibility, and a light emitting diode package having the same.

2. Description of the Related Art

In general, light emitting diodes and electronic elements generate a great deal of heat when operated due to internal resistance or the like. A computer CPU is a typical element generating heat, and a dedicated cooling element is added to such an element generating strong heat to a partially cool the area during operations. However, besides the CPU, other elements attached to a board (substrate) also generate heat, so heat release from the substrate itself with the elements attached thereto emerges as a significant technique.

Such an issue is a factor to be seriously considered in Light Emitting Diode (LED) applications, as light emitting diodes have an array structure in their employment in various fields of application. In general, in order to use light emitting diodes as an illumination lamp, they must have a luminance of thousands of candelas per unit area. However, as it is difficult for a single light emitting diode chip to have such a high level of luminance, a plurality of light emitting diode arrays are commonly configured to obtain the required level of luminance. The issue faced in forming such an array in the related art is effectively maximizing light generated from each light emitting diode, while minimizing it into heat, to thereby maximize light emission levels, and emitting the generated heat to the exterior of the chip or substrate as soon as possible.

In the existing printed circuit board (PCB), when a light emitting diode array is attached, a portion of the heat generated from the light emitting diodes themselves is released through the volume of the light emitting diodes, and the other remaining heat is released toward a lead line itself or toward a lower portion of the PCB through the lead line.

The PCB made of a plastic material does not have good heat release characteristics, so a relatively small amount of heat is released through the board. Thus, when an element generating excessive heat is mounted on the board, because its heat is not properly released, the element malfunctions or its life span is shortened. This is the same in the case of a high luminance light emitting diode, a laser diode, or in arrays thereof.

Thus, one of solutions to the problem in the related art is attaching a structure for improving heat release and reflection efficiency to each element during a manufacturing process and attaching such an individual element to a PCB. For example, each element may have a structure having protrusions and depressions in order to increase the surface area available for heat dissipation, or may be made of a material having effective heat absorption force or heat releasing force.

In addition, a metal core PCB using a metal member having good heat transmission characteristics has been proposed. The metal core PCB includes a metal substrate made of aluminum, a polymer insulation layer formed on the metal substrate, and electrical wiring formed on the polymer insulation layer. Although the metal core PCB has good heat release characteristics when compared with the general PCB made of a plastic material, its fabrication cost is high because it uses high-priced polymer having a relatively high thermal conductivity. In addition, its reflexibility and heat release characteristics are degraded by the polymer insulation layer.

### SUMMARY OF THE INVENTION

An aspect of the present invention provides a metal substrate for a light emitting diode (LED) package having high heat release properties, high luminance, and high reflexibility, and an LED package having the same.

According to an aspect of the present invention, there is provided a substrate for a light emitting diode package, including: a metal plate; an insulation oxide layer formed on a portion of the surface of the metal plate; a first conductive pattern formed on one region of the insulation oxide layer and providing a light emitting diode mounting area; and a second conductive pattern formed on another region of the insulation oxide layer such that it is separated from the first conductive pattern.

A region of the metal plate exposed as the insulation oxide layer is formed on a portion of the metal plate may be obtained as the same material as that of the insulation oxide layer is formed and then removed.

The insulation oxide layer may be an anode oxide film formed by performing an anodizing process on the metal plate.

The substrate for an LED package may further include first and second external mounting pads formed on the first and second conductive patterns, respectively.

The substrate for an LED package may further include first and second external mounting pads electrically connected with the first and second conductive patterns via a through hole formed at the metal plate, and the metal plate may be exposed as the insulation oxide layer is removed from the region where the first and second external mounting pads have not been formed.

According to another aspect of the present invention, there is provided a driving circuit substrate for a light emitting diode package, including: a metal plate; an insulation oxide layer formed on a portion of the surface of the metal plate; and a first conductive pattern formed at one region of the insulation oxide layer and providing a light emitting diode package mounting area and a second conductive pattern formed at another region of the insulation oxide layer such that it is separated from the first conductive pattern.

According to another aspect of the present invention, there is provided a method for fabricating a metal substrate for a light emitting diode package, including: forming an insulation oxide layer on a surface of a metal plate; forming a first conductive pattern at one region of the insulation oxide layer and providing a light emitting diode package mounting area and a second conductive pattern formed at another region of the insulation oxide layer such that it is separated from the first conductive pattern; and removing the insulation oxide layer from a region where the first and second conductive patterns have not been formed to expose the metal plate.

The insulation oxide layer may be formed by performing an anodizing process on the metal plate.

The method for fabricating a metal substrate for an LED package may further include: forming a through hole at the metal plate and forming first and second external mounting pads electrically connected with the first and second conductive patterns through the through hole; and may further include: removing the insulation oxide layer from a region where the first and second external mounting pads have not been formed to expose the metal plate.

According to another aspect of the present invention, there is provided an LED package including: a metal plate; an insulation oxide layer formed on a portion of a surface of the metal plate; a second conductive pattern formed at one region of the insulation oxide layer and providing an LED mounting area and a second conductive pattern formed at another region of the insulation oxide layer such that it is separated from the first conductive pattern; an LED mounted on the first conductive pattern and electrically connected with the second conductive pattern; and a transparent resin covering the LED.

The LED package may further include: first and second external mounting pads formed on the first and second conductive patterns, respectively.

The LED package may further include: first and second reflective films formed on the first and second conductive patterns and first and second external mounting pads penetrating the first and second reflective films.

The LED packet may further include: first and second external mounting pads formed in a penetrating manner at the metal plate and electrically connected with the first and second conductive patterns.

The LED packet may further include: first and second external mounting pads formed in a penetrating manner at the metal plate and electrically connected with the first and second conductive patterns, and a reflective film formed on the first and second conductive patterns.

### BRIEF DESCRIPTION OF THE DRAWINGS

The above and other aspects, features and other advantages of the present invention will be more clearly understood from the following detailed description taken in conjunction with the accompanying drawings, in which:

FIG. 1a is a perspective view of a metal substrate according to an exemplary embodiment of the present invention;

FIG. 1b is a sectional view taken along line I-I′ of FIG. 1;

FIG. 2 is a perspective view of a driving circuit substrate of a light emitting diode (LED) package according to an exemplary embodiment of the present invention;

FIGS. 3a to 3f are sectional views showing the sequential processes of a method for fabricating a metal substrate for an LED package, and the LED package according to one exemplary embodiment of the present invention;

FIGS. 4a to 4f are sectional views showing the sequential processes of a method for fabricating a metal substrate for an LED package, and the LED package according to another exemplary embodiment of the present invention; and

FIGS. 5 to 8 are sectional views showing an LED package according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

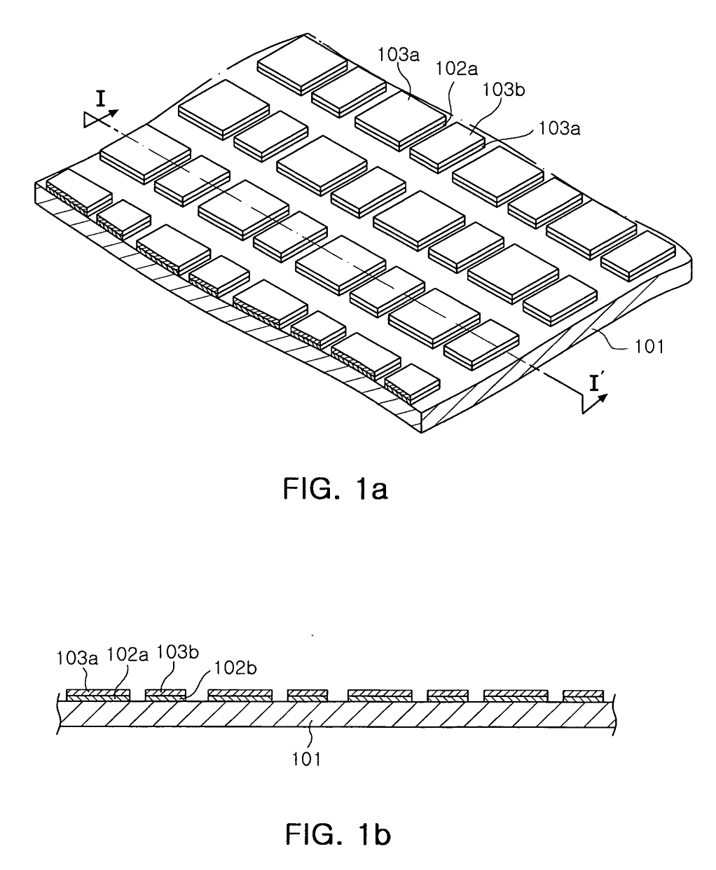

FIG. 1a is a perspective view of a metal substrate according to an exemplary embodiment of the present invention, and FIG. 1b is a sectional view taken along line I-I′ of FIG. 1.

With reference to FIGS. 1a and 1b, the metal substrate includes a metal plate 101, insulation oxide layers 102a and 102b formed on portions of the surface of the metal plate 101, a first conductive pattern 103a formed on one region 102a of the insulation oxide layer and providing a mounting area of a light emitting diode (LED), and a second conductive pattern 103b formed on another region 102b of the insulation oxide layer such that it is separated from the first conductive pattern.

In the present exemplary embodiment, the metal plate 101 is exposed from regions where the first and second conductive patterns 103a and 103b are not formed. The exposed metal plate regions may be regions obtained after the same material as that of the insulation oxide layer is formed and then removed.

The metal substrate 100 according to the present exemplary embodiment is a metal core PCB, and the metal plate 101 is provided as a base substrate of the metal substrate. However, the metal plate 101 is not limited thereto and may be made of aluminum (Al), magnesium (Mg), titanium (Ti), zinc (Zn), tantalum (Ta), ferrite (Fe), nickel (Ni), and alloys thereof. Preferably, the metal plate is made of a metal which has good heat transmission characteristics and can be anodized.

The insulation oxide layers 102a and 102b are formed on one or both surfaces of the metal plate 101. Although not limited, the insulation oxide layers 102a and 102b may be an anodized film formed by performing anodizing on the metal plate 101. When the metal plate 101 is made of aluminum, the insulation oxide layers 102a and 102b may be aluminum anodized insulation films Al₂O₃, which have relatively high heat transmission characteristics of about 10 W/mK to 30 W/mK.

Preferably, the insulation oxide layers 102a and 102b may be formed to have a thickness sufficient to insulate the first and second conductive patterns 103a and 103b. The insulation oxide layers 102a and 102b may have a thickness of 10 μm to 50 μm, but are not limited thereto.

The conductive patterns 103a and 103b may be formed by using a plating process (electroless plating and electroplating), metal deposition, or an ink jet printing method. The conductive patterns 103a and 103b may be formed to have an initially designed pattern, or may be formed through a patterning process after the formation of a conductive film.

The conductive patterns 103a and 103b include a first conductive pattern 103a providing the LED mounting area and the second conductive pattern 103b separated from the first conductive pattern 103a. The first conductive pattern 103a may be a member on which an LED is mounted, and the second conductive pattern 103b may be a member to which a wire for applying current to the LED is coupled.

In the metal substrate 100 according to the present exemplary embodiment, the regions of the insulation oxide layer where the conductive patterns 103a and 103b are not formed are removed to expose the metal plate 101. Namely, regions of the insulation oxide layer other than the regions 102a and 102b for insulating the first and second conductive patterns 103a and 103b are removed.

Because the regions of the insulation oxide layer are removed, the metal plate 101 may be used directly as a heat transmission path, more effectively releasing heat generated from the LED mounted on the metal substrate 101. In addition, degradation of LED reflexibility and luminance due to the insulation oxide layer can be prevented.

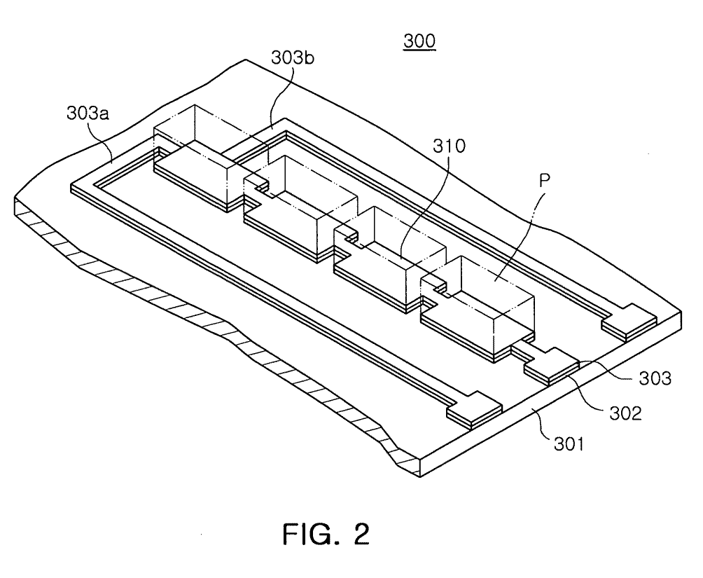

The metal substrate 100 may be used as a driving circuit substrate of an LED package. FIG. 2 is a perspective view of a driving circuit substrate of an LED package according to an exemplary embodiment of the present invention. With reference to FIG. 2, the driving circuit substrate of an LED package includes a metal plate 301, an insulation oxide layer 302 formed on portions of the surface of the metal plate 301, a first conductive pattern 303a providing a mounting area 310 of an LED package (P), and a second conductive pattern 303b formed at a different region of the insulation oxide layer such that it is separated from the first conductive pattern 303a.

Other regions of the insulation oxide layer where the first and second conductive patterns are not formed are removed to expose the metal plate 301.

In the LED package driving circuit substrate according to the present exemplary embodiment, because the regions of the insulation oxide layer where the first and second conductive patterns are not formed are removed, the metal plate 101 may be directly used as a heat transmission path, more effectively releasing heat generated from the LED package mounted on the metal substrate 101. In addition, the degradation of LED reflexibility and luminance due to the insulation oxide layer can be prevented.

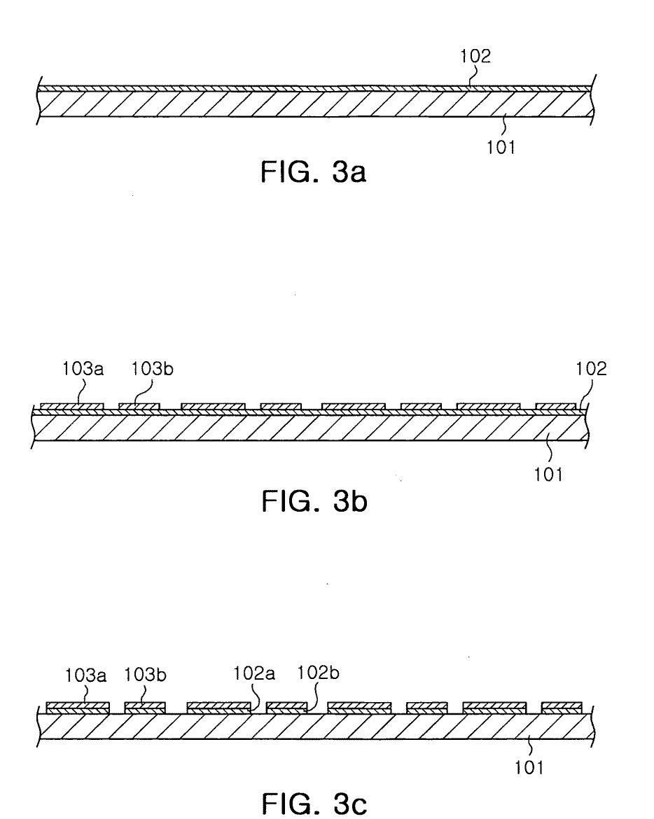

FIGS. 3a to 3f are sectional views showing the sequential processes of a method for fabricating a metal substrate for an LED package, and the LED package according to one exemplary embodiment of the present invention.

The metal substrate for an LED package and the method for fabricating the LED package according to one exemplary embodiment of the present invention will now be described with reference to FIGS. 3a to 3f.

First, as shown in FIG. 3a, the insulation oxide layer 102 is formed on the surface of the metal plate 101. As described above, the insulation oxide layers 102a and 102b may be formed by performing an anodizing process on the metal plate 101.

In more detail, the anodizing process may be performed by putting the metal plate 101 in an electrolyte such as a boric acid, phosphate, sulphuric acid, chromic acid, etc., and applying an anode to the metal plate 101 and a cathode to the electrolyte.

In this case, preferably, the insulation oxide layer 102 is formed to be sufficiently thick to provide an electric insulation between the first and second conductive patterns.

Next, as shown in FIG. 3b, the first and second conductive patterns 103a and 103b are formed on the insulation oxide layer 102. The conductive patterns 103a and 103b may be formed by using a plating process (electroless plating and electroplating), metal deposition, or an ink jet printing method. The conductive patterns 103a and 103b may be formed to have an initially designed pattern, or may be formed through a patterning process after the formation of a conductive film.

Then, as shown in FIG. 3c, the regions of the insulation oxide layer 102 where the first and second conducive patterns 103a and 103b are not formed are removed to expose the metal plate 101.

The method for exposing the metal plate 101 by removing the insulation oxide layer is not particularly limited.

For example, as shown, the insulation oxide layer is formed on the entire surface of the metal plate 101, the first and second conductive patterns are formed, and the insulation oxide layer at the regions where the conductive pattern is not formed can be selectively removed. For example, an etchant reacting with the insulation oxide layer may be used to selectively remove the insulation oxide layer.

Although not shown, it may be selectively formed from the beginning by using a masking pattern when the insulation oxide layer is formed.

When the insulation oxide layer is formed through an anodizing process, first, a proper mask pattern such as a resist pattern or an oxide pattern is formed on one surface of both surfaces of the metal plate 101, on which anodizing may be performed. Accordingly, anodizing may occur selectively on the metal plate, and an anodized film may be formed to selectively open (expose) the metal plate.

In this manner, the metal plate for an LED package is fabricated.

Subsequently, as shown in FIG. 3d, an LED 111 is mounted on the first conductive pattern 103a, and the LED 111 and the second conductive pattern 103b are electrically connected by using a wire 112 or the like.

The method of mounting the LEDs is not particularly limited. A die bonding method in which solder or the like is deposited and then thermal treatment is performed at a certain temperature, a eutectic bonding method either fluxless or with flux, or the like, may be used.

Although not shown, the LEDs may be electrically connected by using a flip-chip bonding method.

Thereafter, as shown in FIG. 3e, first and second external mounting pads 114a and 114b are formed on the first and second conductive patterns. And then, a transparent resin 113 may be formed to cover the LED 111 and the wire 112.

Alternatively, as shown in FIG. 3f, first and second reflection films 125a and 125b may be formed on the first and second conductive patterns. In this case, the first and second external mounting pads 124a and 124b may be formed to penetrate the first and second reflection films 125a and 125b.

Thereafter, a transparent resin 123 may be formed to cover an LED 121 and a wire 122.

Then, the metal substrate for an LED package is cut based on the pair of first and second conductive patterns in order to separate the LED. Accordingly, the LED package is fabricated.

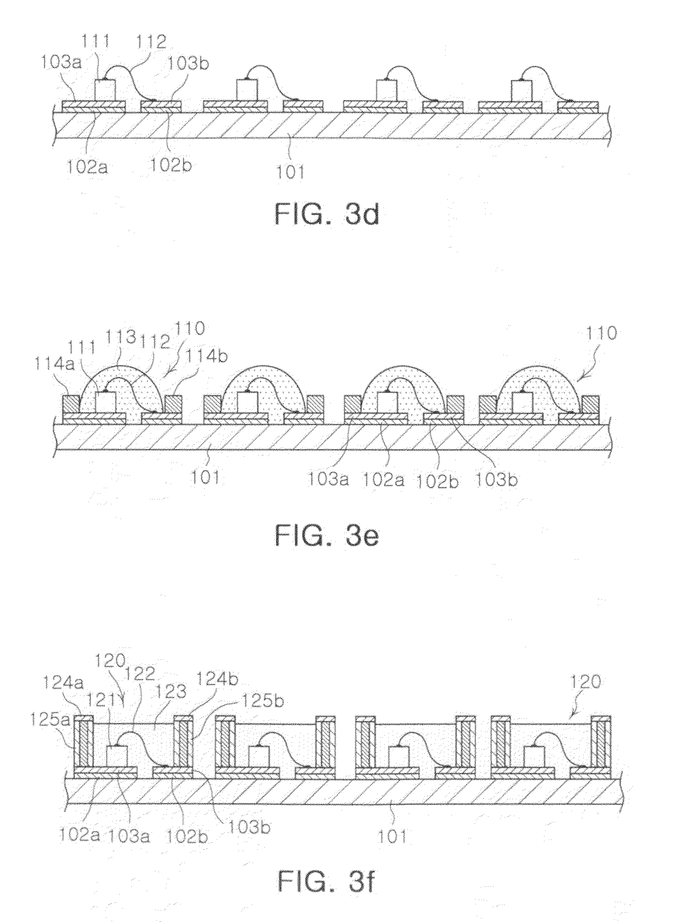

FIGS. 4a to 4f are sectional views showing the sequential processes of a method for fabricating a metal substrate for an LED package, and the LED package according to another exemplary embodiment of the present invention.

The metal substrate for an LED package and the method for fabricating the LED package according to another exemplary embodiment of the present invention will now be described with reference to FIGS. 4a to 4f. Different elements from those of the former exemplary embodiment will be described, and detailed description of the same elements will be omitted.

First, as shown in FIG. 4a, a through hole (h) is formed on one surface of a metal plate 201, and an insulation oxide layer 202 is formed on the surface of the metal plate 201 including an inner wall of the through hole (h). As described above, the insulation oxide layer 202 may be formed by performing an anodizing process on the metal plate 201.

Next, as shown in FIG. 4b, the first and second conductive patterns 203a and 203b are formed on the insulation oxide layer 202. Also, first and second external mounting pads 204a and 204b are formed to be electrically connected with the first and second conductive patterns 203a and 203b, including a via fill process of the through hole (h).

Then, as shown in FIG. 4c, the regions of the insulation oxide layer 202 where the first and second conducive patterns 203a and 203b and the first and second external mounting pads 204a and 204b are not formed are removed to expose metal plate 201.

Subsequently, as shown in FIG. 4d, an LED 211 is mounted on the first conductive pattern 203a, and the LED 211 and the second conductive pattern 203b are electrically connected by using a wire 212 or the like.

Although not shown, the LED may be electrically connected by using a flip-chip bonding method.

Thereafter, as shown in FIG. 4e, a transparent resin 213 is formed to cover the LED 211 and the wire 212.

Alternatively, as shown in FIG. 4f, first and second reflection films 225a and 225b may be formed on the first and second conductive patterns. Thereafter, a transparent resin 223 may be formed to cover the LED 221 and a wire 222.

Then, the metal substrate for an LED package is cut based on the pair of first and second conductive patterns in order to separate the LED. Accordingly, the LED package is fabricated.

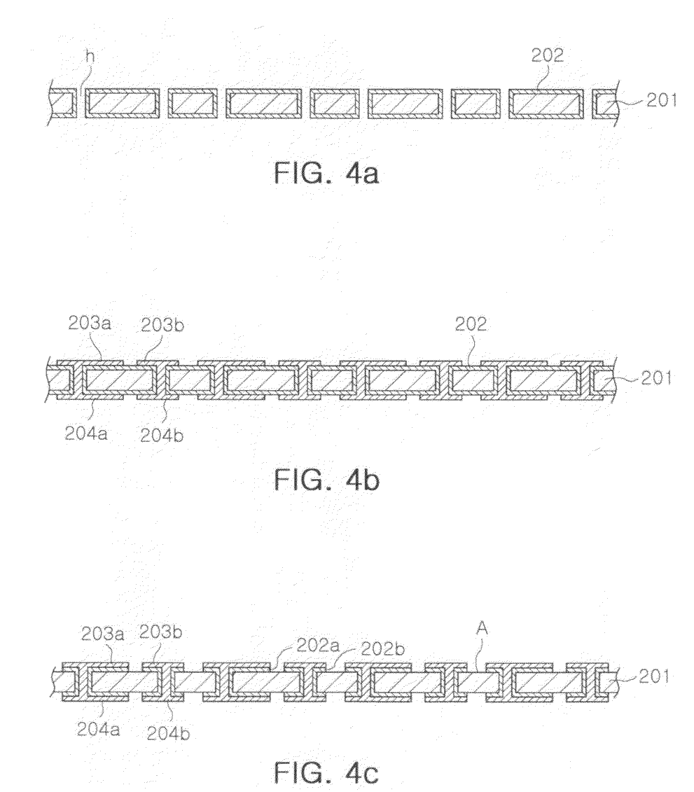

FIGS. 5 to 8 are sectional views showing an LED package according to an exemplary embodiment of the present invention. Different elements from those of the former exemplary embodiment will be described, and detailed description of the same elements will be omitted.

With reference to FIG. 5, an LED package 110 according to an exemplary embodiment of the present invention includes the metal plate 101, the insulation oxide layers 102a and 102b formed on portions of the surface of the metal plate, the first conductive pattern 103a formed on one region 102a of the insulation oxide layer and providing a mounting area of an LED, and the second conductive pattern 103b formed on another region 102b of the insulation oxide layer such that it is separated from the first conductive pattern, an LED 111 mounted on the first conductive pattern 103a and electrically connected with the second conductive pattern 103b, and the transparent resin 113 covering the LED. In the LED package according to the present exemplary embodiment, the regions of the insulation oxide layer where the first and second conductive patterns are not formed are removed to expose the metal plate.

The LED 111 is electrically connected with the second conductive pattern 103b by the wire 112, and molded by the transparent resin 113 to protect the LED 111 and the wire 112.

The LED package 110 further includes first and second external mounting pads 114a and 114b electrically connected with the first and second conductive patterns 103a and 103b.

In the LED according to the present exemplary embodiment, because the regions of the insulation oxide layer where the first and second conductive patterns are not formed are removed, the metal plate may be directly used as a heat transmission path, more effectively releasing heat generated from the LED mounted on the metal substrate. In addition, the degradation of LED reflexibility and luminance due to the insulation oxide layer can be prevented.

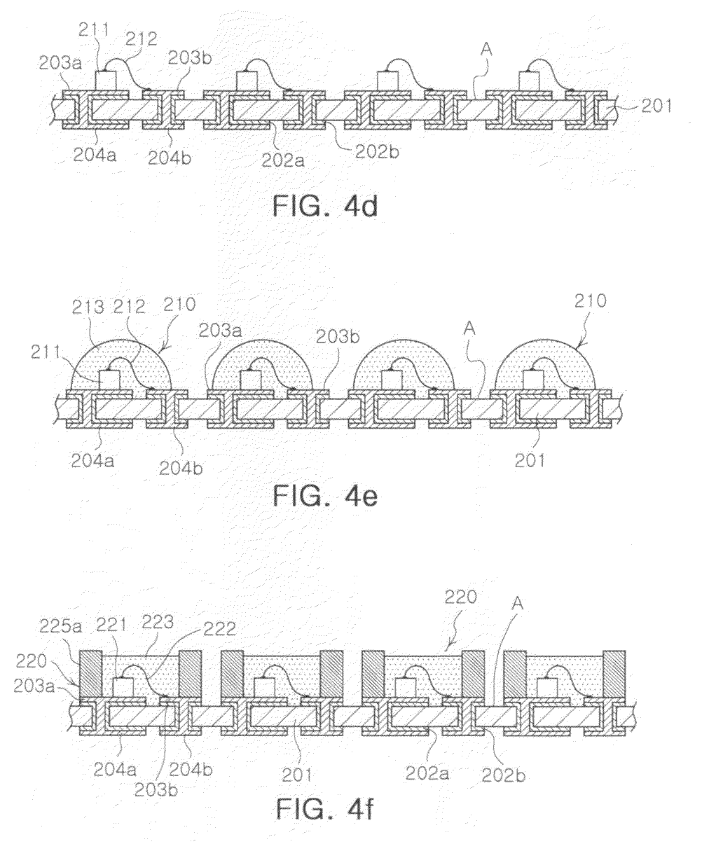

With reference to FIG. 6, an LED package 120 according to an exemplary embodiment of the present invention includes the metal plate 101, the insulation oxide layers 102a and 102b formed on portions of the surface of the metal plate, the first conductive pattern 103a formed on one region 102a of the insulation oxide layer and providing a mounting area of an LED, and the second conductive pattern 103b formed on another region 102b of the insulation oxide layer such that it is separated from the first conductive pattern, an LED 121 mounted on the first conductive pattern 103a and electrically connected with the second conductive pattern 103b, and the transparent resin 123 covering the LED.

In the LED package according to the present exemplary embodiment, the regions of the insulation oxide layer where the first and second conductive patterns are not formed are removed to expose the metal plate.

The LED 121 is electrically connected with the second conductive pattern 103b by the wire 122, and molded by the transparent resin 123 to protect the LED 121 and the wire 122.

In addition, the LED package 120 includes first and second reflection films 125a and 125b formed on the first and second conductive patterns 103a and 103b, and further includes first and second external mounting pads 124a and 124b penetrating the first and second reflection films.

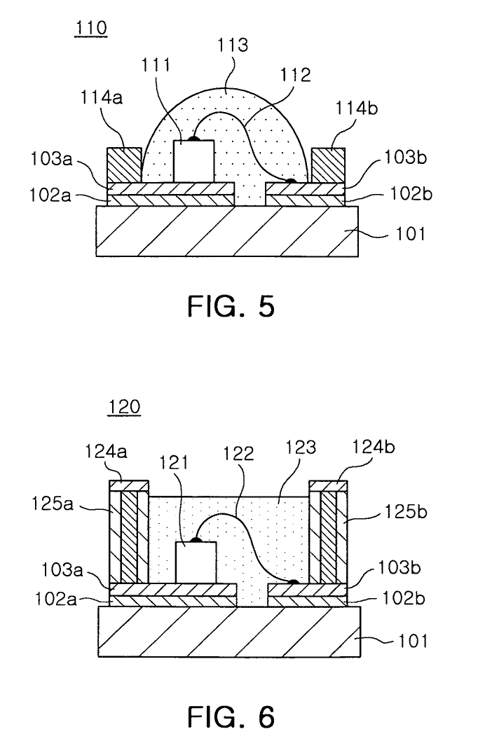

With reference to FIG. 7, an LED package 210 according to an exemplary embodiment of the present invention includes the metal plate 201, the insulation oxide layers 202a and 202b formed on portions of the surface of the metal plate 201, the first conductive pattern 203a formed on one region 202a of the insulation oxide layer and providing a mounting area of an LED, and the second conductive pattern 203b formed on another region 202b of the insulation oxide layer such that it is separated from the first conductive pattern, an LED 211 mounted on the first conductive pattern 203a and electrically connected with the second conductive pattern 203b, and the transparent resin 213 covering the LED. In the LED package according to the present exemplary embodiment, the regions of the insulation oxide layer where the first and second conductive patterns are not formed are removed to expose the metal plate.

The LED 211 is electrically connected with the second conductive pattern 203b by the wire 212, and molded by the transparent resin 213 to protect the LED 211 and the wire 212.

In addition, the LED package includes first and second external mounting pads 204a and 204b electrically connected with the first and second conductive patterns 203a and 203b via a through hole formed in the metal plate 201.

The regions of the insulation oxide layer where the first and second external mounting pads 204a and 204b are not formed are removed to expose the metal plate.

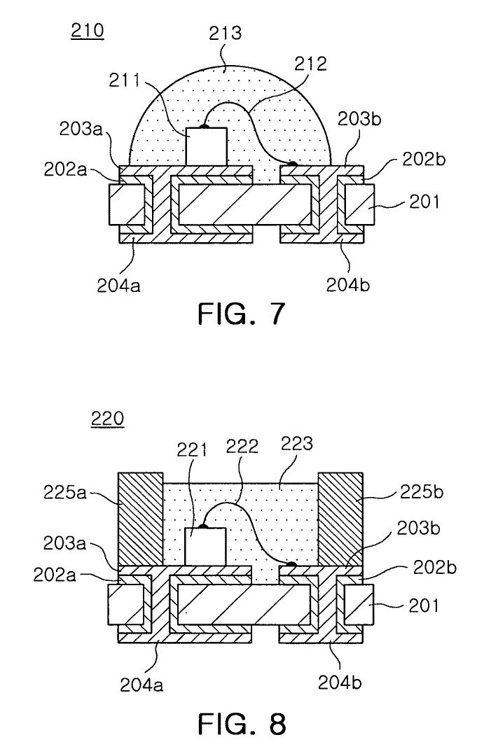

With reference to FIG. 8, an LED package 220 according to an exemplary embodiment of the present invention includes the metal plate 201, the insulation oxide layers 202a and 202b formed on portions of the surface of the metal plate 201, the first conductive pattern 203a formed on one region 202a of the insulation oxide layer and providing a mounting area of an LED, and the second conductive pattern 203b formed on another region 202b of the insulation oxide layer such that it is separated from the first conductive pattern, an LED 221 mounted on the first conductive pattern 203a and electrically connected with the second conductive pattern 203b, and the transparent resin 223 covering the LED. In the LED package according to the present exemplary embodiment, the regions of the insulation oxide layer where the first and second conductive patterns are not formed are removed to expose the metal plate.

The LED 221 is electrically connected with the second conductive pattern 203b by the wire 222, and molded by the transparent resin 223 to protect the LED 221 and the wire 222.

In addition, the LED package includes the first and second external mounting pads 204a and 204b electrically connected with the first and second conductive patterns 203a and 203b via a through hole formed in the metal plate 201. The regions of the insulation oxide layer where the first and second external mounting pads 204a and 204b are not formed are removed to expose the metal plate.

Also, the LED package includes first and second reflection films 225a and 225b formed on the first and second conductive patterns 203a and 203b.

As set forth above, according to exemplary embodiments of the invention, because other regions of the insulation oxide layer than the regions for insulating the conductive patterns are removed, the metal plate can be directly used as a heat transmission path. Thus, heat generated from the LED mounted on the metal substrate 101 can be more effectively released. In addition, degradation of LED reflexibility and luminance due to the insulation oxide layer can be prevented.

While the present invention has been shown and described in connection with the exemplary embodiments, it will be apparent to those skilled in the art that modifications and variations can be made without departing from the spirit and scope of the invention as defined by the appended claims.

What is claimed is:

1. A substrate for a light emitting diode (LED) package, the substrate comprising:
a metal plate;
an insulation oxide layer formed on a portion of the surface of the metal plate;
a first conductive pattern formed on one region of the insulation oxide layer and providing a light emitting diode mounting area; and
a second conductive pattern formed on another region of the insulation oxide layer such that it is separated from the first conductive pattern.

2. The substrate of claim 1, wherein a region of the metal plate exposed as the insulation oxide layer is formed on a portion of the metal plate is obtained as the same material as that of the insulation oxide layer is formed and then removed.

3. The substrate of claim 1, wherein the insulation oxide layer is an anode oxide film formed by performing an anodizing process on the metal plate.

4. The substrate of claim 1, further comprising:
first and second external mounting pads formed on the first and second conductive patterns, respectively.

5. The substrate of claim 1, further comprising:
first and second external mounting pads electrically connected with the first and second conductive patterns via a through hole formed at the metal plate.

6. The substrate of claim 5, wherein the metal plate is exposed as the insulation oxide layer is removed from the region where the first and second external mounting pads have not been formed.

7. A driving circuit substrate for a light emitting diode package, the substrate comprising:
a metal plate;
an insulation oxide layer formed on a portion of the surface of the metal plate; and
a first conductive pattern formed at one region of the insulation oxide layer and providing a light emitting diode package mounting area and a second conductive pattern formed at another region of the insulation oxide layer such that it is separated from first conductive pattern; and

8. A method for fabricating a metal substrate for a light emitting diode package, the method comprising:
forming an insulation oxide layer on a surface of a metal plate;
forming a first conductive pattern at one region of the insulation oxide layer and providing a light emitting diode package mounting area and a second conductive pattern formed at another region of the insulation oxide layer such that it is separated from the first conductive pattern;
removing the insulation oxide layer from a region where the first and second conductive patterns have not been formed to expose the metal plate.

9. The method of claim 8, wherein the insulation oxide layer is formed by performing an anodizing process on the metal plate.

10. The method of claim 8, further comprising:
forming a through hole at the metal plate and forming first and second external mounting pads electrically connected with the first and second conductive patterns through the through hole.

11. The method of claim 10, further comprising:
removing the insulation oxide layer from a region where the first and second external mounting pads have not been formed to expose the metal plate.

12. A light emitting diode (LED) package comprising:
a metal plate;
an insulation oxide layer formed on a portion of a surface of the metal plate;
a second conductive pattern formed at one region of the insulation oxide layer and providing an LED mounting area and a second conductive pattern formed at another region of the insulation oxide layer such that it is separated from the first conductive pattern;
an LED mounted on the first conductive pattern and electrically connected with the second conductive pattern; and
a transparent resin covering the LED.

13. The package of claim 12, further comprising:
first and second external mounting pads formed on the first and second conductive patterns, respectively.

14. The package of claim 12, further comprising:
first and second reflective films formed on the first and second conductive patterns and first and second external mounting pads penetrating the first and second reflective films.

15. The package of claim 12, further comprising:
first and second external mounting pads formed in a penetrating manner at the metal plate and electrically connected with the first and second conductive patterns.

16. The package of claim 12, further comprising:
first and second external mounting pads formed in a penetrating manner at the metal plate and electrically connected with the first and second conductive patterns, and a reflective film formed on the first and second conductive patterns.
